(19) United States
(12) Patent Application Publication
(10) Pub. No.: US 2011/0110022 A1
(43) Pub. Date: May 12, 2011

(54) PORTABLE TERMINAL DEVICE WITH WATERPROOF STRUCTURE

(75) Inventors: Masashi Kumagai, Kanagawa (JP); Shingo Kume, Kanagawa (JP)

(73) Assignee: PANASONIC CORPORATION, Osaka (JP)

(21) Appl. No.: 12/999,870

(22) PCT Filed: Feb. 2, 2009
(86) PCT No.: PCT/JP2009/000390

§ 371 Date: Dec. 17, 2010

(30) Foreign Application Priority Data
Jun. 19, 2008 (JP) 2008-159973

(51) Int. Cl. H05K 5/02

(52) U.S. Cl. 361/679.01

(57) ABSTRACT

A portable terminal apparatus for implementing a sure waterproof function with small components and a small number of components is provided.

The portable terminal apparatus with a waterproof structure includes a first casing 1 having an opening 14, a cable 5 for electrically connecting an electronic circuit of the inside of the first casing 1 to another electronic circuit through the opening 14, and a waterproof packing 7 which has an insertion hole 7b formed to penetrate so as to allow the cable 5 to be inserted and which is inserted into the opening 14. The waterproof packing 7 has a cylindrical shape and includes a first waterproof press-fitting rib 7c on an outside and a second waterproof press-fitting rib 7d on an inside, and the first waterproof press-fitting rib 7c and the second waterproof press-fitting rib 7d are disposed in positions mutually displaced in a length direction.

### TECHNICAL FIELD

The present invention relates to a portable terminal apparatus with a waterproof structure, and particularly to the portable terminal apparatus such as a folding mobile telephone with the waterproof structure using a cable for connecting electronic circuits housed in respective casings.

### BACKGROUND ART

In a mobile telephone which is a portable terminal apparatus used at any places and environments, the mobile telephone with waterproof is practically used. For example, an apparatus there is known a cable for connecting electronic circuits housed in respective casings which is waterproofed using a waterproof tube (for example, see Patent Document 1 and Patent Document 2).

Patent Document 1: JP-A-2006-216687

Patent Document 2: JP-A-2005-325849

### DISCLOSURE OF THE INVENTION

### Problem to be Solved by the Invention

The portable terminal apparatus is required to be reduced in size and weight, by saving space with a small number of components. Consequently, when a waterproof function is applied to the portable terminal apparatus, a sure waterproof structure with small components and a small number of components is needed.

### Means for Solving the Problem

The invention uses a waterproof structure to provide a portable terminal apparatus with a waterproof structure comprising: a casing having an opening; a cable for electrically connecting an electronic circuit provided inside the casing to another electronic circuit through the opening; and a waterproof packing which has an insertion hole formed to penetrate so as to allow the cable to be inserted and which is inserted into the opening, wherein the waterproof packing has a cylindrical shape and comprises a first waterproof press-fitting rib provided on an outside of the cylindrical shape and a second waterproof press-fitting rib provided on an inside of the cylindrical shape, and the first waterproof press-fitting rib and the second waterproof press-fitting rib are disposed at positions mutually displaced in an axial direction of the insertion hole. By this configuration, mutual influence between deformation of the first waterproof press-fitting rib and deformation of the second waterproof press-fitting rib can be reduced, so that the portable terminal apparatus for implementing a sure waterproof function with small components and a small number of components can be provided.

The invention includes the portable terminal apparatus with the waterproof structure wherein in the first waterproof press-fitting rib of the waterproof packing, an axial section of the insertion hole has a semicircular shape, and wherein in the second waterproof press-fitting rib of the waterproof packing, an axial section of the insertion hole has a rectangular or trapezoidal shape (where a corner is rounded). By this configuration, when the waterproof packing is inserted into the opening, for example, at the time of assembly, the insertion is easy since the axial section of the insertion hole of the first waterproof press-fitting rib has the semicircular shape. Further, even when a force is applied to the cable, for example, in the case of opening and closing the casing, a contact area is kept to be large and waterproof properties can be maintained surely, since the axial section of the insertion hole of the second waterproof press-fitting rib has the rectangular shape or the trapezoidal shape (where the corner is rounded).

The invention includes the portable terminal apparatus with the waterproof structure wherein the waterproof packing comprises a locking portion in an end portion of the cylindrical shape. By this configuration, the locking portion functions as a stopper at the time of pushing the waterproof packing into the casing, so that the waterproof packing can be positioned in the optimum position suitable for waterproof.

The invention includes the portable terminal apparatus with the waterproof structure wherein in the waterproof packing, the first waterproof press-fitting rib is disposed in a position closer to an end portion of the cylindrical shape opposite to the locking portion than the second waterproof press-fitting rib. By this configuration, by inserting the waterproof packing into the opening of the casing so that the first waterproof press-fitting rib becomes the inside, that is, the locking portion of the waterproof packing becomes the outside, the first waterproof press-fitting rib can be kept in the inside even when the waterproof packing becomes a state of slightly out of the opening of the casing in the case of applying a force to the cable, for example, in the case of opening and closing the casing. Therefore, the waterproof properties can be maintained and the waterproof properties can be increased.

The invention includes the portable terminal apparatus with the waterproof structure wherein the cylindrical shape of the waterproof packing is an elliptically cylindrical shape. By this configuration, pushable space for pressing both sides of the cable inserted into the waterproof packing at the time of pushing the waterproof packing into the casing in an axial direction of the insertion hole can be obtained while achieving thinning of the casing by a dimension of a minor axis of the elliptically cylindrical shape. As a result, the waterproof packing can be pushed into the insertion hole of the casing by pressing the pushable space.

The invention includes the portable terminal apparatus with the waterproof structure comprising a retaining member which is detachably provided adjacent to the waterproof packing and which has a cable guide groove . As a result, even when an external force is applied to the cable, the retaining member maintains the cable in a predetermined shape and implements a waterproof function of maintaining close contact between the cable and the insertion hole of the waterproof packing.

### ADVANTAGES OF THE INVENTION

According to the invention, the portable terminal apparatus for implementing a sure waterproof function with small components and a small number of components can be provided.

### BRIEF DESCRIPTION OF THE DRAWINGS

FIG. 1 is a plan view at the time of opening casings of a portable terminal apparatus with a waterproof structure according to a first embodiment of the invention.

FIG. 2 is an exploded plan view showing the portable terminal apparatus with the waterproof structure according to the first embodiment of the invention.

FIG. 3 is a plan view of a casing portion of the portable terminal apparatus with the waterproof structure according to the first embodiment of the invention.

FIG. 4 is a plan view at the time of integrating a cable with waterproof packing of the portable terminal apparatus with the waterproof structure according to the first embodiment of the invention.

FIG. 5(a) is a plan view of the waterproof packing of the portable terminal apparatus with the waterproof structure according to the first embodiment of the invention, and FIG. 5(b) is a front view of the waterproof packing of the portable terminal apparatus with the waterproof structure according to the first embodiment of the invention, and FIG. 5(c) is a sectional view of the waterproof packing of the portable terminal apparatus with the waterproof structure according to the first embodiment of the invention.

FIG. 6 is a perspective view of a retaining member of the portable terminal apparatus with the waterproof structure according to the first embodiment of the invention.

FIG. 7(a) is a diagram showing the cable and the waterproof packing of the portable terminal apparatus with the waterproof structure according to the first embodiment of the invention, and FIG. 7(b) is a diagram showing a state of the time of fitting the cable and the waterproof packing of the portable terminal apparatus with the waterproof structure according to the first embodiment of the invention into a first casing, and FIG. 7(c) is a diagram showing a state of fitting the cable and the waterproof packing of the portable terminal apparatus with the waterproof structure according to the first embodiment of the invention into the first casing.

### DESCRIPTION OF REFERENCE SIGNS

1 FIRST CASING

2 SECOND CASING

3 CONNECTION PORTION

5 CABLE

7 PACKING FOR CABLE (WATERPROOF PACKING)

7a LOCKING PORTION

7b INSERTION HOLE

7c PROTRUSION PORTION (FIRST WATERPROOF PRESS-FITTING RIB)

7d RECTANGULAR SHAPE SECTIONAL PROTRUSION PORTION (SECOND WATERPROOF PRESS-FITTING RIB)

7e PUSHABLE SPACE

9 RETAINING MEMBER

14, 24 HOLE FOR PACKING (OPENING)

### BEST MODE FOR CARRYING OUT THE INVENTION

### First Embodiment

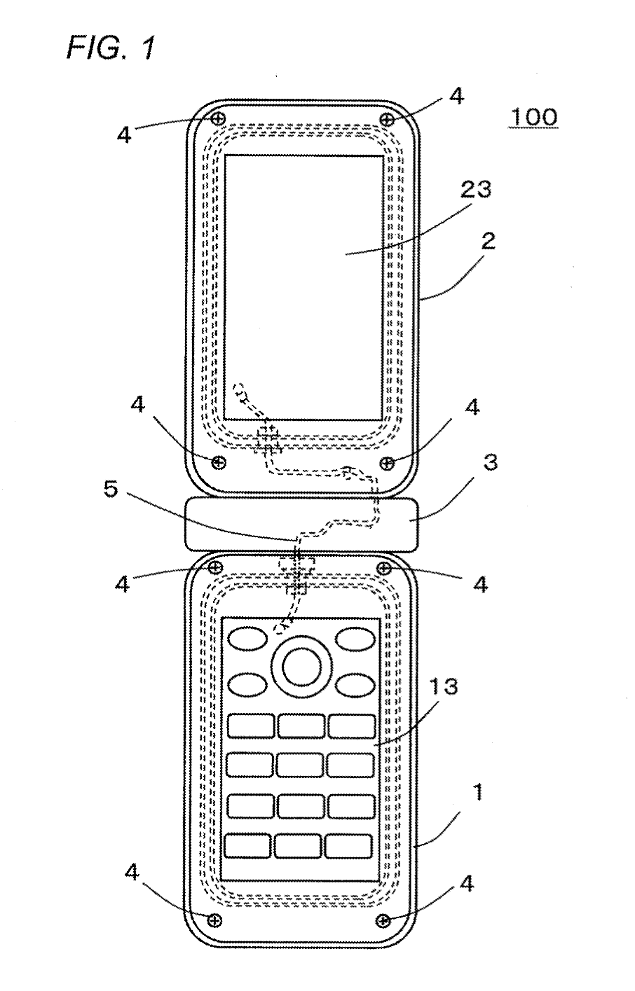

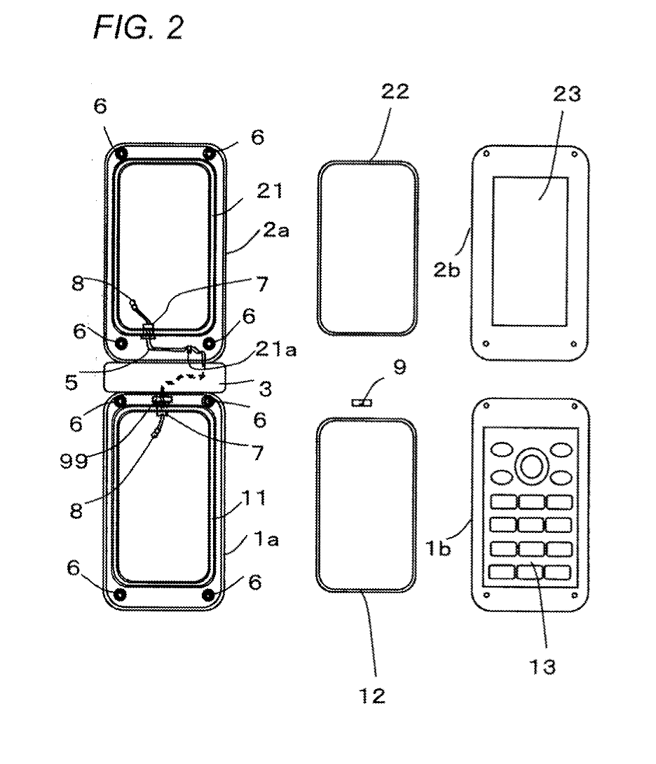

FIG. 1 shows a plan view at the time of opening casings of a folding portable terminal apparatus with a waterproof structure according to a first embodiment of the invention. A portable terminal apparatus 100 with a waterproof structure according to the first embodiment of the invention includes a first casing 1 including an operation portion such as a ten-key pad for inputting a telephone number etc., a second casing 2 including a liquid crystal display portion, and a connection portion 3 configured to support both the casings so as to allow the casings to open and close. FIG. 2 shows a plan view at the time of detaching-an operation panel 13 from the first casing 1 of the portable terminal apparatus 100 with the waterproof structure according to the first embodiment of the invention and also detaching a display panel 23 from the second casing 2.

The first casing 1 includes two portions (a lower case 1a and a lower cover 1b), and by sandwiching waterproof packing 12 between the two portions and fixing the portions by plural screws 4, water is prevented from entering the casing. The second casing 2 is similarly includes two portions (an upper case 2a and an upper cover 2b) and by sandwiching waterproof packing 22 between the two portions and fixing the portions by plural screws 4, water is prevented from entering the casing. The first casing 1 and the second casing 2 are preferably made of resin such as a PA resin which is a relatively hard resin.

The operation panel 13 is disposed in the first casing 1 (lower cover 1b). The display panel 23 is disposed in the second casing 2 (upper cover 2b). A printed board (not shown in FIG. 1) in which an electronic circuit for performing operation control etc. is mounted is housed in the first casing 1. A printed board in which an electronic circuit for display is mounted is housed in the second casing 2. Then, the printed boards are connected by a cable 5.

As shown in FIG. 2, a groove 11 for packing holding is disposed in the first casing 1 (lower case 1a), and a groove 21 for packing holding is disposed in the second casing 2 (upper case 2a). The packing 12 for first casing and the packing 22 for second casing are used in a state of being respectively fitted into the groove 11 for packing holding and the groove 21 for packing holding.

In addition, the packing 12 for first casing and the packing 22 for second casing are set in sizes swelling from the groove 11 for packing holding and the groove 21 for packing holding in the state of being respectively fitted into the groove 11 for packing holding and the groove 21 for packing holding. As a result, a region surrounded by the groove 11 for packing holding of the first casing 1 and a region surrounded by the groove 21 for packing holding of the second casing 2 form hermetically closed space and are made waterproof by respectively screwing the lower case 1a and the lower cover 1b, and the upper case 2a and the upper cover 2b.

In FIG. 2, a retaining member 9 of the waterproof packing for cable is formed in U shape as described below, and is fixed to the first casing 1 by being fitted into a fixing groove 99 for retaining member of the first casing 1 (lower case 1a). Numeral 6 is a screw hole and the screw 4 is screwed as shown in FIG. 1.

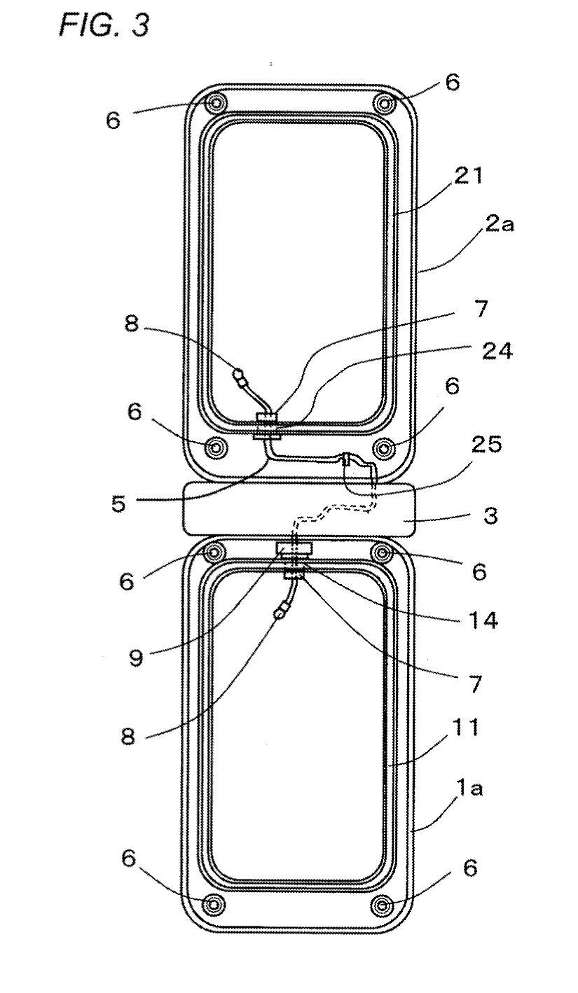

FIG. 3 is a plan view enlarging the first casing 1 (lower case 1a), the second casing 2 (upper case 2a) and the connection portion 3 of FIG. 2. FIG. 3 shows that a hole 14 for packing which is an opening for fixing packing 7 for cable is disposed in a side wall of the groove 11 for packing holding of the first casing 1 and the packing 7 for cable is fitted into its hole 14 for packing. Similarly, a hole 24 for packing which is an opening for fixing packing 7 for cable is disposed in a side wall of the groove 21 for packing holding of the second casing 2 and the packing 7 for cable is fitted into its hole 24 for packing.

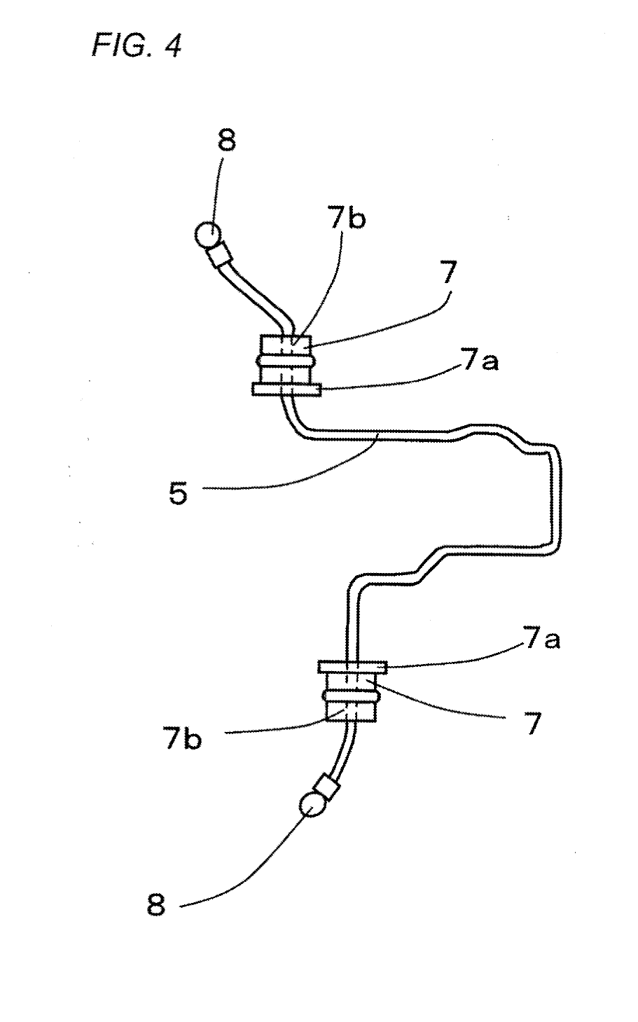

FIG. 4 is a diagram showing the cable 5 for connecting the printed board of the first casing 1 to the printed board of the second casing 2 together with a pair of the packing 7 for cable. As shown in FIG. 4, connecting terminals 8 for making connection to the printed boards are previously fastened to both ends of the cable 5. Also, the cable 5 is inserted into insertion holes 7b in a state of setting retaining portions 7a of a pair of the packing 7 for cable to the outsides of the casings (a state of being set to the sides separate from the connecting terminals 8). The cable 5 is assembled in a shape as shown in FIG. 4 and then is incorporated into the first casing 1 and the second casing 2 as shown in FIG. 3.

In addition, the retaining member 9 of the waterproof packing for cable of the first casing 1 of FIG. 3 is detached from the first casing 1 (lower case 1a) once before the cable 5 is incorporated, and the cable 5 is incorporated and the packing 7 for cable is fitted into the hole 14 for packing of the first casing 1 and thereafter, the retaining member 9 is fixed to the fixing groove 99 for retaining member of the first casing 1 (lower case 1a) so as to be pressed astride from an upper portion of the cable 5.

The retaining member 9 has action of retaining the packing 7 for cable in the hole 14 for packing of the first casing 1 and action of making the cable 5 maintain a predetermined relative angle with respect to the packing 7 for cable (that is, maintain a straight state). When the cable 5 is attached obliquely with respect to the packing 7 for cable, a gap occurs between the cable 5 and the packing 7 for cable and water tends to enter, but the retaining member 9 maintains the angle between the cable 5 and the packing 7 for cable and thereby, a waterproof function is enhanced.

A hook 25 for cable of the second casing 2 of FIG. 3 is a hook for hooking and fixing the cable 5 after the packing 7 for cable is fitted into the hole 24. for packing which is the opening of the second casing 2. The hook 25 for cable is disposed by being bonded to or molded integrally to the second casing 2. A length of the cable 5 ranging from the hole 24 for packing of the second casing 2 to the connection 3 is longer than a length of the cable 5 ranging from the hole 14 for packing of the first casing 1 to the connection 3. As a result, the angle between the cable 5 and the packing 7 for cable can be maintained by hooking and fixing the cable 5 to the hook 25 for cable in a position separate from the hole 24 for packing. This enhances the waterproof function between the cable 5 and the packing 7 for cable also in the second casing 2.

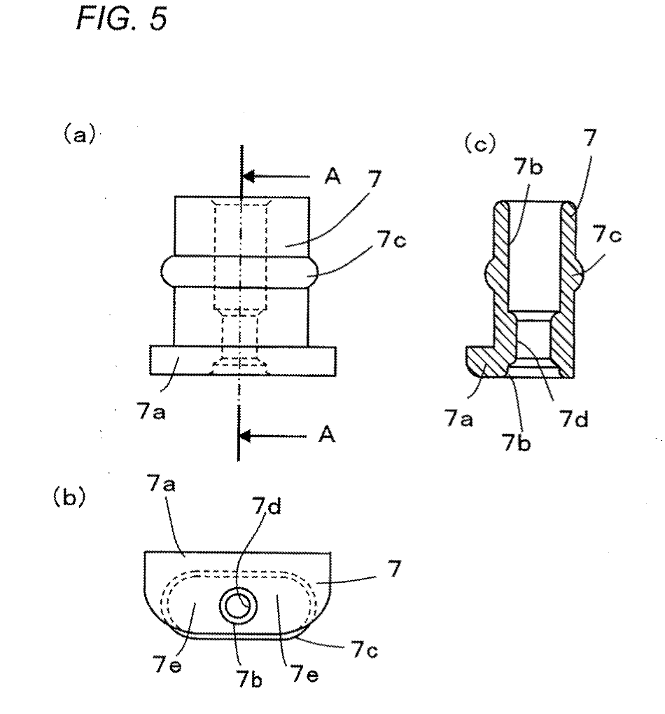

FIG. 5 shows a shape of the single packing 7 for cable. FIG. 5(a) shows a plan view of the packing 7 for cable, and FIG. 5(b) shows a front view of the packing 7 for cable, and FIG. 5(c) shows a sectional view taken on line A-A in FIG. 5(a) of the packing 7 for cable, that is, an axial sectional view of the insertion hole.

The packing 7 for cable has a cylindrical shape in which the insertion hole 7b is opened in the center. A sectional shape orthogonal to the axis of the insertion hole 7b of the cylindrical shape portion has an elliptic shape. A locking portion 7a whose external shape is made larger than the cylindrical portion is formed in the cylindrical end. Since this locking portion 7a functions as a stopper at the time of pushing the packing 7 for cable into the casing, the packing 7 for cable can be positioned in the optimum position suitable for waterproof.

Also, as shown in FIG. 5(b), both sides of the insertion hole 7b of the lower portion of the locking portion 7a are used as pushable space 7e in the case of pushing the packing 7 for cable into the hole 24 for packing which is the opening of the casing. Here, the cylindrical shape of the packing 7 for cable is formed in an elliptically cylindrical shape.

By this configuration, the pushable space for pressing both sides of the cable 5 inserted into the packing 7 for cable at the time of pushing the packing 7 for cable into the casing in an axial direction of the insertion hole 7b can be obtained while achieving thinning of the casing by a dimension of a minor axis of the elliptically cylindrical shape. As a result, the packing 7 for cable can be pushed into the insertion hole 7b of the casing by pressing the pushable space 7e. In addition, a sectional shape (sectional shape orthogonal to the axis of the insertion hole 7b) of the insertion hole 7b of the packing 7 for cable is a circular shape according to a sectional shape of the cable 5.

A protrusion portion 7c which is a first waterproof press-fitting rib is annularly disposed on an outer surface of the cylindrical portion of the packing 7 for cable. Here, an axial sectional shape of the insertion hole of the protrusion portion 7c is a semicircular shape. A rectangular shape sectional protrusion portion 7d with a section (where a corner is rounded) of a rectangular shape, which is a second waterproof press-fitting rib, is formed on an inner surface of the cylindrical portion.

Here, an axial sectional shape of the insertion hole of the rectangular shape sectional protrusion portion 7d has the section (where the corner is rounded) of the rectangular shape. In this rectangular shape sectional protrusion portion 7d, the inside diameter is smaller than that of the insertion hole 7b. Also, the axial section of the insertion hole of the rectangular shape sectional protrusion portion 7d has the rectangular shape (where the corner is rounded).

By this configuration, in the case of inserting the packing 7 for cable into the hole 14, 24 for packing which is the opening, for example, at the time of assembly, while the insertion is easy since the axial section of the insertion hole 7b of the protrusion portion 7c which is the first waterproof press-fitting rib has the semicircular shape. Further, even when a force is applied to the cable 5, for example, in the case of opening and closing the casing, a contact area is kept to be large and waterproof properties can be maintained surely, since the axial section of the insertion hole 7b of the rectangular shape sectional protrusion portion 7d which is the second waterproof press-fitting rib has the rectangular shape (where the corner is rounded).

In addition, as the second waterproof press-fitting rib, the rectangular shape sectional protrusion portion 7d in which the axial sectional shape of the insertion hole has the section (where the corner is rounded) of the rectangular shape is described, but instead of this, even using a trapezoidal shape sectional protrusion portion in which the axial sectional shape of the insertion hole has a section (where a corner is rounded) of a trapezoidal shape, a similar effect is obtained.

In the first embodiment of the invention, the protrusion portion 7c which is the first waterproof press-fitting rib disposed on the outer surface of the cylindrical portion is formed in a position far from the locking portion 7a, and the rectangular shape sectional protrusion portion 7d which is the second waterproof press-fitting rib disposed on the inner surface of the cylindrical portion is formed in a position near to the locking portion 7a, and both of the protrusion portions are separated so as not to overlap in the axial direction of the insertion hole.

Consequently, an influence at the time of compressing the protrusion portion 7c is minimized on the rectangular shape sectional protrusion portion 7d and also an influence at the time of compressing the rectangular shape sectional protrusion portion 7d is minimized on the protrusion portion 7c.

That is, since the protrusion portion 7c which is the first waterproof press-fitting rib and the rectangular shape sectional protrusion portion 7d which is the second waterproof press-fitting rib are disposed in the positions mutually displaced in the axial direction of the insertion hole 7b, the mutual influence between deformation of the protrusion portion 7c which is the first waterproof press-fitting rib and deformation of the rectangular shape sectional protrusion portion 7d which is the second waterproof press-fitting rib can be reduced, so that the portable terminal apparatus for implementing a sure waterproof function with small components and a small number of components can be provided.

Also, in the packing 7 for cable which is waterproof packing, the protrusion portion 7c which is the first waterproof press-fitting rib is disposed in a position closer to the cylindrical shape end opposite to the locking portion 7a than the rectangular shape sectional protrusion portion 7d which is the second waterproof press-fitting rib.

By this configuration, by inserting the packing 7 for cable into the hole 14, 24 for packing which is the opening of the casing so that the protrusion portion 7c becomes the inside, that is, the locking portion 7a of the packing 7 for cable becomes the outside, the protrusion portion 7c can be kept in the inside from the locking portion 7a or the rectangular shape sectional protrusion portion 7d, even when the packing 7 for cable becomes a state of slightly coming out of the hole 14, 24 for packing which is the opening of the casing in the case of applying a force to the cable 5, for example, in the case of opening and closing the casing. Therefore, waterproof properties can be maintained and the waterproof properties can be increased.

Also, in the first embodiment of the invention, the configuration without mutual influence between the amount of compression of the protrusion portion 7c and the amount of compression of the rectangular shape sectional protrusion portion 7d has an advantage capable of being made waterproof surely since the protrusion portion 7c and the rectangular shape sectional protrusion portion 7d make close contact with the casing or the cable 5 by necessary close contact forces. Also, there is an advantage capable of finally adjusting the amount of compression individually in metal mold manufacture of finally adjusting the amount of compression of the protrusion portion 7c and the amount of compression of the rectangular shape sectional protrusion portion 7d.

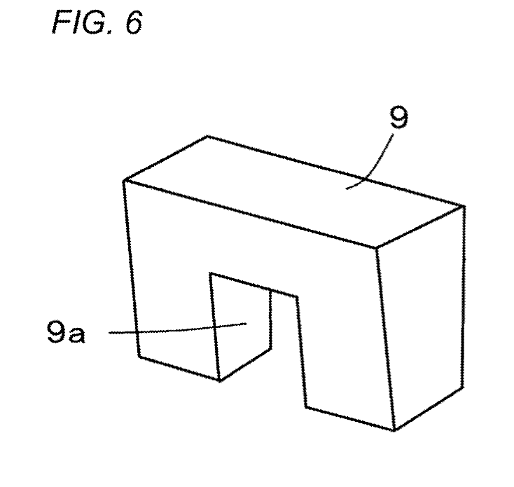

FIG. 6 is a perspective view of the single retaining member 9 of the waterproof packing for cable. The retaining member 9 is a component with substantially a U shape, and is fitted into the fixing groove 99 for retaining member of the first casing so as to cover the cable 5 with a U-shaped groove portion 9a.

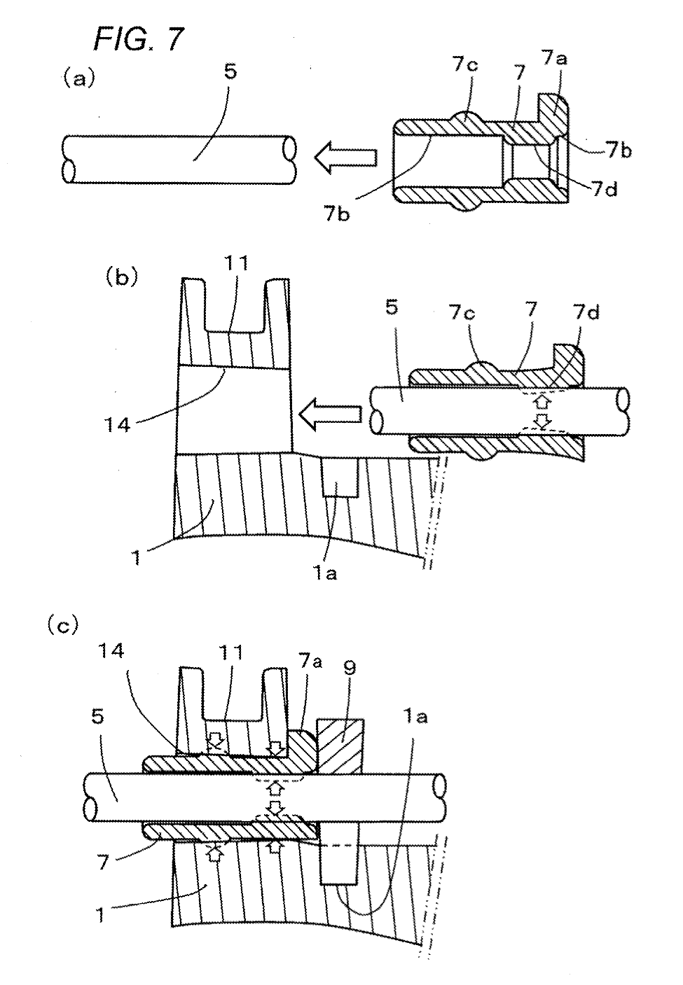

FIG. 7 shows a procedure for inserting the cable 5 into the insertion hole 7b of the packing 7 for cable and fitting the packing 7 for cable into the hole 14 for packing which is the opening of the first casing 1 and fitting the retaining member 9 into the fixing groove 99 for retaining member of the first casing from the upper portion of the cable 5.

FIG. 7(a) shows a state of the cable 5 and the packing 7 for cable before the cable 5 is inserted into the insertion hole'7b of the packing 7 for cable. FIG. 7(b) shows a state just before the packing 7 for cable is fitted into the hole 14 for packing of the first casing 1 after the cable 5 is inserted into the insertion hole 7b of the packing 7 for cable. FIG. 7(c) shows a state of the time of fitting the retaining member 9 into the fixing groove 99 for retaining member of the first casing from the upper portion of the cable 5 after the packing 7 for cable is fitted into the hole 14 for packing of the first casing 1.

As shown in FIG. 7(b), when the cable 5 is inserted into the insertion hole 7b of the packing 7 for cable, the rectangular shape sectional protrusion portion 7d which is the second waterproof press-fitting rib of the packing for cable makes close contact with the cable 5 and is integrated with the cable 5. Then, as shown by a left arrow of FIG. 7(b), the packing 7 for cable is fitted into the hole 14 for packing of the first casing 1 and when the packing for cable axially presses the pushable space 7e of both sides of the insertion hole 7b shown in FIG. 5(b), the pressing force can be applied to the packing 7 itself for cable.

As a result, the packing 7 itself for cable is pressed and the packing 7 for cable can be fitted into the hole 14 for packing which is the opening of the first casing as shown in FIG. 7(c). The protrusion portion 7c which is the first waterproof press-fitting rib of the packing 7 for cable is compressed by the hole 14 for packing of the first casing and makes close contact, and water is prevented from entering between the first casing 1 and the packing 7 for cable.

In addition, a size of the hole 14 for packing of the first casing is increased in a tapered shape in a direction of pushing the packing 7 for cable. As a result, once the cable 5 and the packing 7 for cable are simultaneously pushed into the hole 14 for packing of the first casing, the packing 7 for cable is resistant to coming out after the push.

Also, as shown in FIG. 7(c), when the packing 7 for cable is fitted until the locking portion 7a abuts on an end face of the hole 14 for packing of the first casing, an outer peripheral surface of the cylindrical portion in the rectangular shape sectional protrusion portion 7d is also pressed by the hole 14 for packing of the first casing. As a result, the outer peripheral surface of the cylindrical portion in the rectangular shape sectional protrusion portion 7d of the packing 7 for cable makes close contact with the hole 14 for packing of the first casing and water is prevented from entering between the first casing 1 and the packing 7 for cable.

Also, the rectangular shape sectional protrusion portion 7d of the packing for cable is further compressed, so that the packing 7 for cable makes closer contact with the cable 5 and a waterproof effect is enhanced.

In addition, a material of the packing 7 for cable is not particularly described, but a packing material such as silicon rubber can be used. Also, a shape of the hole 14, 24 for packing which is the opening of the casing is described as the hole such as the hole 14, 24 for packing, but the shape may be formed in an opening hole in which one side in which the hole 14, 24 for packing is connected to the groove 11, 21 for packing holding is opened.

According to the first embodiment of the invention as described above, the portable terminal apparatus for implementing a sure waterproof function with small components and a small number of components can be provided.

Also, in the first embodiment of the invention, the portable terminal apparatus 100 of a type of opening and closing the first casing 1 and the second casing 2 is described, but the invention can also be used in, for example, a portable terminal apparatus of a type of sliding the second casing 2 with respect to the first casing 1 or a portable terminal apparatus of a type of longitudinally and transversely opening and closing the first casing 1 and the second casing 2.

The present application is based on Japanese patent application (patent application No. 2008-159973) filed on Jun. 19, 2008, and the contents of the patent application are hereby incorporated by reference.

The various embodiments of the invention have been described above, but the invention is not limited to the items shown in the embodiment described above, and the invention intends to make change and application by persons skilled in the art based on well-known techniques and the mention of the description, and the change and application are included in the scope of protection.

### INDUSTRIAL APPLICABILITY

The invention can be applied to a portable terminal apparatus with a waterproof structure for connecting two casings, including a folding mobile telephone, a folding game machine, etc. Also, waterproof packing of the invention can be applied to a portable terminal apparatus with a waterproof structure for connecting one casing.

1-6. (canceled)

7. A foldable portable terminal apparatus with a waterproof structure, comprising:
a first casing having an opening;
a second casing;
a connection portion configured to support the first casing and the second casing so as to allow the first casing and the second casing to open and close;
a cable for electrically connecting an electronic circuit provided inside the first casing to another electronic circuit provided inside the second casing through the opening and the connection portion;
a waterproof packing which has an insertion hole formed to penetrate so as to allow the cable to be inserted and which is inserted into the opening; and
a retaining member configured to maintain an angle of the cable with respect to the waterproof packing and prevents a removal of the cable by covering a portion of the cable between the waterproof packing and the connection portion.

8. The foldable portable terminal apparatus according to claim 7, comprising a retaining member fixing groove which is configured to fix the retaining member and which is provided between the opening of the first casing and an end portion of the first casing closer to the connection portion,
wherein the retaining member is fixed to the retaining member fixing groove which covering the portion of the cable between the waterproof packing and the connection portion.

9. The foldable portable terminal apparatus according to claim 7,
wherein in the waterproof packing, a number of the insertion hole is one, and a shape thereof is an elliptically cylindrical shape.

10. The foldable portable terminal apparatus according to claim 9,
wherein the waterproof packing comprises a first waterproof press-fitting rib provided on an outside of the elliptically cylindrical shape and a second waterproof press-fitting rib provided on an inside of the elliptically cylindrical shape, and the first waterproof press-fitting rib and the second waterproof press-fitting rib are disposed at positions mutually displaced in an axial direction of the insertion hole.

11. The foldable portable terminal apparatus with the waterproof structure according to claim 10,
wherein the waterproof packing comprises a locking portion in an end portion of the elliptically cylindrical shape.

12. The foldable portable terminal apparatus with the waterproof structure according to claim 11,
wherein in the waterproof packing, the first waterproof press-fitting rib is disposed in a position closer to an end portion of the elliptically cylindrical shape opposite to the locking portion than the second waterproof press-fitting rib.

13. The foldable portable terminal apparatus with the waterproof structure according to claim 10,
wherein in the first waterproof press-fitting rib of the waterproof packing, an axial section of the insertion hole has a semicircular shape, and
wherein in the second waterproof press-fitting rib of the waterproof packing, an axial section of the insertion hole has a rectangular or trapezoidal shape.
